(19) United States
(12) Patent Application Publication
(10) Pub. No.: US 2012/0267708 A1
(43) Pub. Date: Oct. 25, 2012

(54) TERMINATION STRUCTURE FOR POWER DEVICES

(76) Inventors: Yung-Fa Lin, Hsinchu City (TW); Shou-Yi Hsu, Hsinchu County (TW); Meng-Wei Wu, Hsinchu City (TW); Main-Gwo Chen, Hsinchu County (TW); Jing-Qing Chan, Taipei City (TW); Yi-Chun Shih, Nantou County (TW)

(21) Appl. No.: 13/234,150

(22) Filed: Sep. 16, 2011

(30) Foreign Application Priority Data
Apr. 21, 2011 (TW) 100113899

(51) Int. Cl. H01L 29/78

(52) U.S. Cl. 257/330; 257/E29.262

(57) ABSTRACT

A termination structure for a power MOSFET device includes a substrate, an epitaxial layer on the substrate, a trench in the epitaxial layer, a first insulating layer within the trench, a first conductive layer atop the first insulating layer, and a column doping region in the epitaxial layer and in direct contact with the first conductive layer. The first conductive layer is in direct contact with the first insulating layer and is substantially level with a top surface of the epitaxial layer. The first conductive layer comprises polysilicon, titanium, titanium nitride or aluminum.

### BACKGROUND OF THE INVENTION

1. Field of the Invention

This present invention generally relates to the field of semiconductor power devices. More particularly, the present invention relates to a termination structure in a power MOSFET with a super-junction.

2. Description of the Prior Art

A power device is used in power management; for example, in a switching power supply, a management integrated circuit in the core or a peripheral region of computer, a backlight power supply, and in an electric motor control. The type of power devices described above include an insulated gate bipolar transistor (IGBT), a metal-oxide-semiconductor field effect transistor (MOSFET), and a bipolar junction transistor (EU), among which the MOSFET is the most widely applied because of its energy saving properties and ability to provide faster switching speeds.

In one kind of power device, a P-type epitaxial layer and an N-type epitaxial layer are alternatively disposed to form several PN junctions inside a body wherein the junctions are vertical to a surface of the body. A structure with the described PN junctions is also called a super-junction structure. In a conventional method for fabricating the super-junction structure, an epitaxial layer of a first conductivity type, e.g. N-type, is formed on a substrate of the first conductivity type. Then, a plurality of trenches is etched into the first conductivity type epitaxial layer by a first mask. A second conductivity type epitaxial layer, e.g. P-type epitaxial layer, is filled into the trenches and the surface of the second conductivity type epitaxial layer is made level with the surface of the first conductivity type epitaxial layer. The trenches are filled with the second conductivity type epitaxial layer and are surrounded by the first conductivity type epitaxial layer. As a result, a super-junction structure with a plurality of PN junctions is formed.

The above-mentioned method has a number of disadvantages. Smooth surfaces cannot be obtained at the sidewall of the trenches via the etching process which may cause some defects on the interfacial surface between the first conductivity epitaxial layer and the second conductivity epitaxial layer. These defects reduce the breakdown voltage of the power device. It is well-known that the super-junction structure described above is usually disposed within a cell region which is surrounded by a termination structure. The design of the termination structure is also important for improving the reliability of the device and avoiding electrical breakdown. In light of the above, there is still a need for fabricating a semiconductor power device with smooth super-junctions which are capable of overcoming the shortcomings and deficiencies of the prior art.

### SUMMARY OF THE INVENTION

To address these and other objectives, the present invention provides a termination structure for power devices, which comprises a substrate of a first conductivity type, an epitaxial layer of the first conductivity type on the substrate, a trench in the epitaxial layer of the first conductivity type, a first insulating layer within the trench, a first conductive layer atop the first insulating layer within the trench, and a column doping region of a second conductivity type disposed in the epitaxial layer of the first conductivity type adjacent to the trench, the column doping region being in direct contact with the first conductive layer, wherein the first conductive layer comprises polysilicon, titanium, titanium nitride or aluminum.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIGS. 1-16 are schematic, cross-sectional diagrams illustrating a method for fabricating a semiconductor power device in accordance with one embodiment of this invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following description, numerous specific details are given to provide a thorough understanding of the invention. It will, however, be apparent to one skilled in the art that the invention may be practiced without these specific details. Furthermore, some well-known system configurations and process steps are not disclosed in detail, as these should be well-known to those skilled in the art.

Likewise, the drawings showing embodiments of the apparatus are semi-diagrammatic and not to scale and some dimensions are exaggerated in the figures for clarity of presentation. Also, where multiple embodiments are disclosed and described as having some features in common, like or similar features will usually be described with like reference numerals for ease of illustration and description thereof.

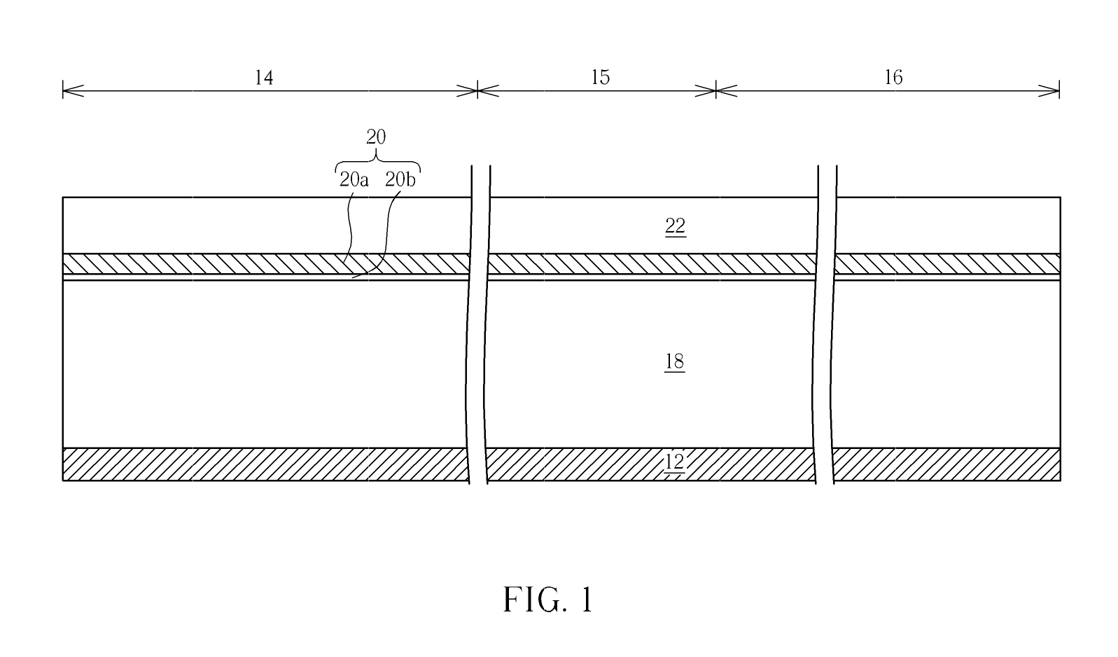

Please refer to FIGS. 1-16, which are schematic diagrams illustrating a method for fabricating a semiconductor power device in accordance with the embodiment of the present invention, wherein a trench type power device is an exemplary embodiment suitable for the present invention.

As shown in FIG. 1, in a preferred embodiment of this invention, a substrate 12 of a first conductivity type is provided which is an N+ silicon substrate and functions as a drain electrode of the semiconductor device. A cell region 14, termination region 16 surrounding the cell region 14, and a transition region 15 disposed between the cell region 14 and the termination region 16 are defined in the substrate 12. The cell region 14 is used to accommodate a semiconductor device and the termination region 16 comprises a voltage sustaining structure which can function as a barrier for preventing the spreading of the high intensity electric field generated from the cell region 14. An epitaxial layer 18 of the first conductivity type is disposed on the substrate 12 through an epitaxial process. According to the embodiment of the invention, the epitaxial layer 18 of the first conductivity type can be an epitaxial layer doped with N−; for example, the epitaxial layer 18 of the first conductivity type can be formed by a CVD process or any other appropriate methods and the epitaxial layer 18 of the first conductivity type can function as a drift layer in the power device. A pad layer 20 which can be divided into two parts is formed on the epitaxial layer 18 of the first conductivity type. The composition of an upper pad layer 20a may be Si₃N₄ and the composition of a lower pad layer 20b may be SiO₂. Then, a hard mask 22, e.g. silicon oxide layer, is formed on the surface of the pad layer 20 by a deposition process.

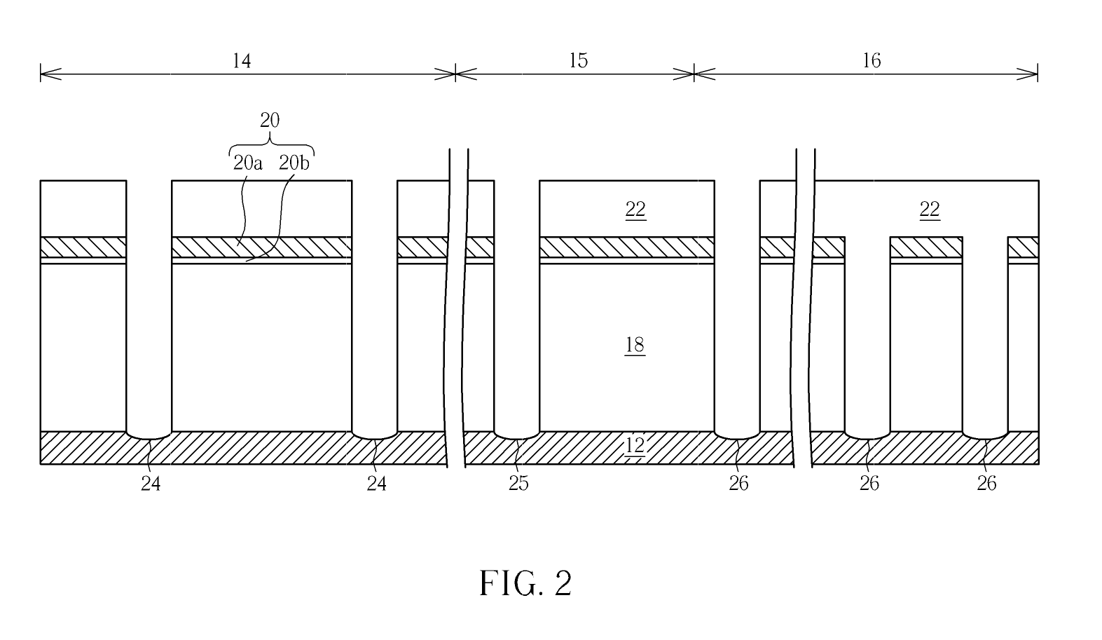

As illustrated in FIG. 2, a photolithography and an etching process is carried out to etch a plurality of trenches 24, 25, 26 into the hard mask 22, pad layer 20, and epitaxial layer 18 in sequence while the trenches 24, 25, 26 are disposed in the cell region 14, the transition region 15, and the termination region 16, respectively. Depending on different engineering demands, the bottom of the trenches 24, 25, 26 can be located in the epitaxial layer 18 or in the substrate 12. For instance, the formation of the trenches 24, 25, 26 can be in the following sequences: a photoresist layer coated on the hard mask 22 is treated with a photolithography process in order to define the location of the trenches; an anisotropic etching process, which uses a patterned photoresist as an etching mask, is performed to transfer the pattern of the patterned photoresist into the hard mask 22 and pad layer 20. The removal of the patterned photoresist is performed followed by a dry etching process, thereby further transferring the pattern into the epitaxial layer 18. The above mentioned method for forming the trenches is only exemplary and the trenches 24, 25, 26 can be fabricated by other methods. In addition, the shape, location, width, depth, length, and number of the trenches are not limited to the trenches 24, 25, 26 shown in FIG. 2. The trenches 24, 25, 26 could be modified for design purposes or manufacturing demands; for instance, the layout of the trenches 24, 25, 26 can be in the form of strips, hexagons, or a spiral-pattern.

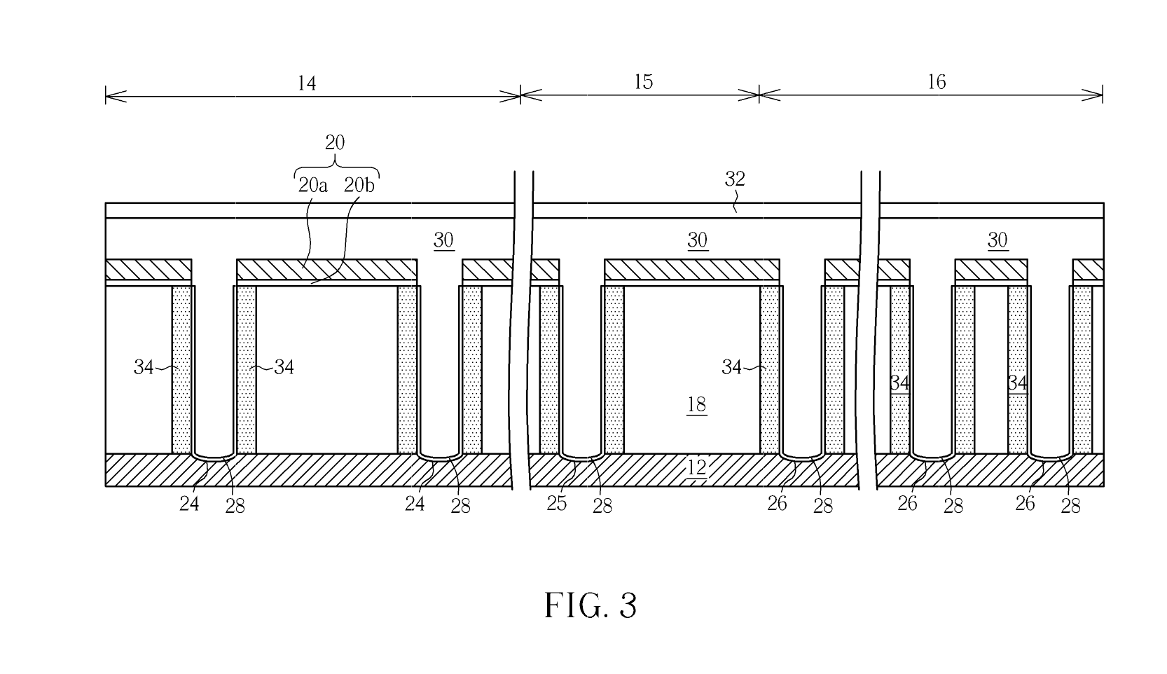

As shown in FIG. 3, the hard mask 22 is removed and a thermal oxidation process is performed to form a buffer layer 28 on the interior surface of the trenches 24, 25, 26. The buffer layer 28 comprising silicon oxide may have a thickness less than 30 nm. It is not recommended to adopt oxynitride or nitride material in the buffer layer as oxynitride may create defects for trapping electrons and nitride materials may impose stress on an interface. A dopant source layer 30 which has the second conductivity type, e.g. P-type, is disposed on the surface of the pad layer 20 and fills up the trenches 24, 25, 26. The composition of the dopant source layer 30 may be borosilicate glass, BSG, but is not limited thereto. The dopant source layer 30 comprising oxide is disposed on the surface of the dopant source layer 30 followed by a thermal drive-in process to diffuse dopants inside the dopant source layer 30 into the epitaxial layer 18. Therefore, a body diffusion region 34 is formed surrounding the trenches 24, 25, 26 in the epitaxial layer 18. As a consequence, a plurality of vertical PN junctions is formed in the epitaxial layer 18, the structure of which is called a super junction.

It is worth noting that the buffer layer 28 is capable of repairing the sidewall of the trenches 24, 25, 26 and can improve a contact between the dopant source layer 30 and the trenches 24, 25, 26. As a result, dopants inside the dopant source regions can diffuse into the epitaxial layer 18 in the well concentration distribution and the depth of all diffused dopants will be approximately the same, therefore forming a smooth PN junction. In sum, the buffer layer 28 can improve the concentration uniformity of the dopants in the epitaxial layer 18 which effectively solves the drawbacks of the rough PN junction associated with the prior art.

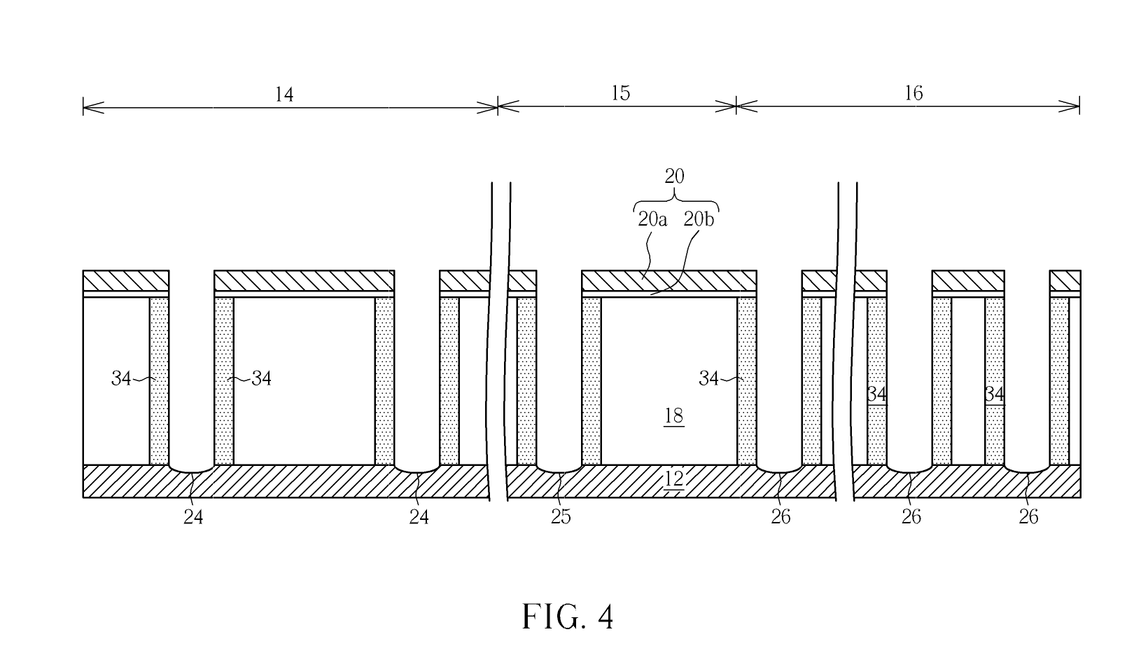

As depicted in FIG. 4, the removal of the cap oxide 32, the dopant source layer 30, and the buffer layer 28 are performed to expose the upper surface of the pad layer 20 and the sidewall of the trenches 24, 25, 26. In addition, according to another embodiment of this invention, after forming the body diffusion region 34, only the cap oxide 32 and the dopant source layer 30 are removed or only the cap oxide 32 is removed. The benefit of the removal of the buffer layer 28 is that the dopant source layer 30 can be removed completely hence the occurrence of residues existing in the trenches can be prevented.

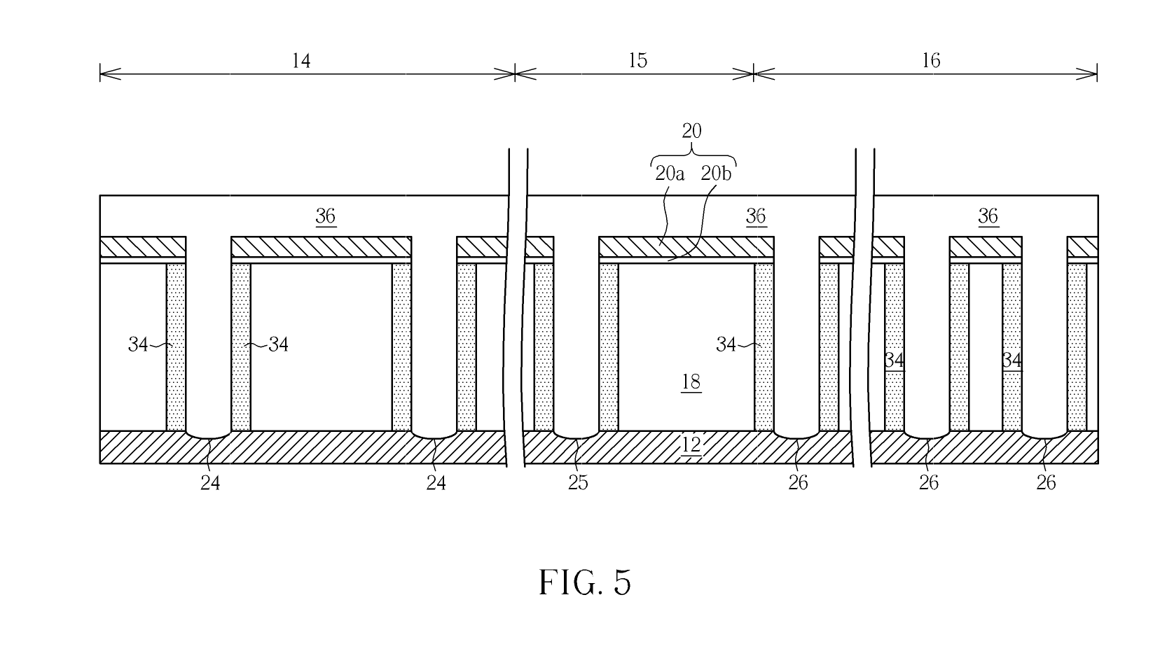

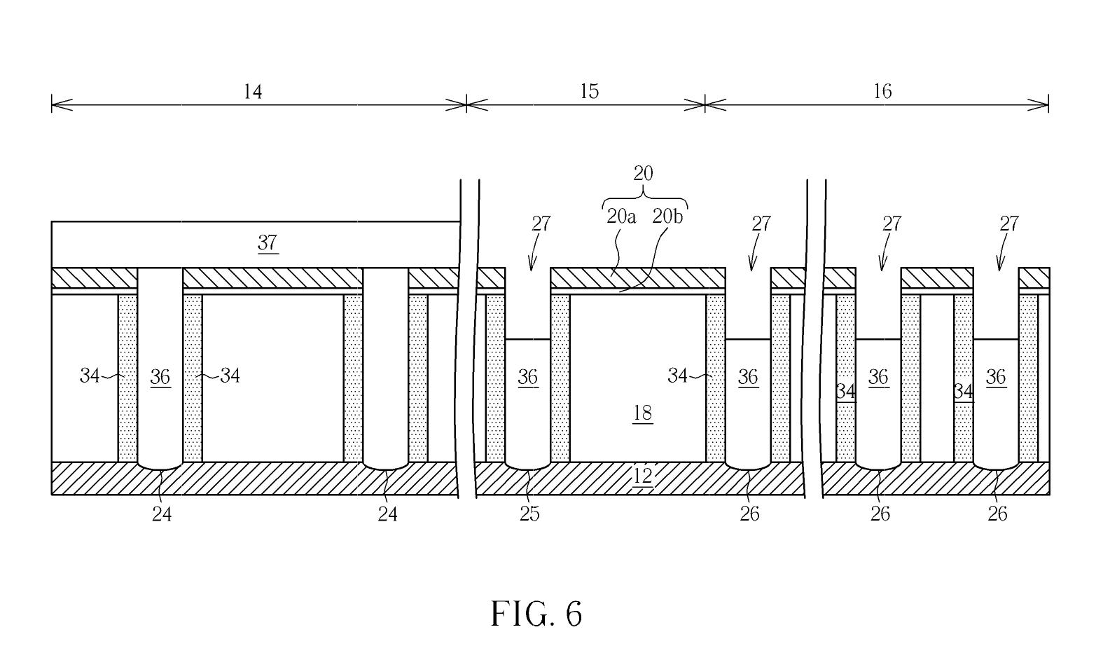

As shown in FIG. 5, a first dielectric layer 36 is formed on the surface of the pad layer 20 and fills up the trenches 24, 25, 26. A CMP process is performed to expose the upper surface of the pad layer 20. As shown in FIG. 6, a photolithography process is carried out to form a patterned photoresist which covers the cell region 14. An etching process is performed to etch regions which are not covered by the photoresist, i.e. the transition region 15 and the termination region 16. At this time, a portion of the first dielectric layer 36 inside the trenches, 25, 26 within the transition region 15 and the termination region 16, respectively, are removed. As a consequence, the upper part of the trenches, 25, 26 is exposed therefore forming a recessed structure 27.

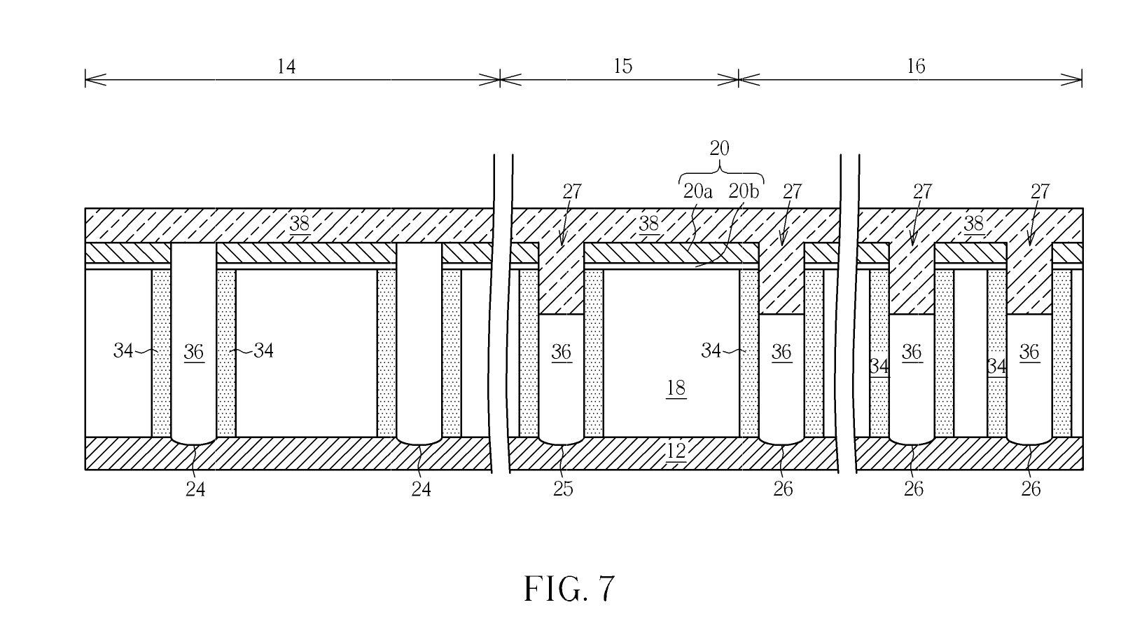

Referring to FIG. 7, the photoresist layer 37 within the cell region 14 is removed. A polysilicon deposition process is performed to form a polysilicon layer 38 within cell region 14, the transition region 15, and the termination region 16. The recessed structure 27 within the transition region 15 and the termination region 16 is filled up by the polysilicon layer 38. Dopants are implanted into the polysilicon layer 38 to improve the conductivity of the polysilicon layer 38 and to make the polysilicon layer 38 be the second conductivity type. In other embodiments, the polysilicon layer 38 can be replaced by Ti, Ti/TiN, Al or other metals.

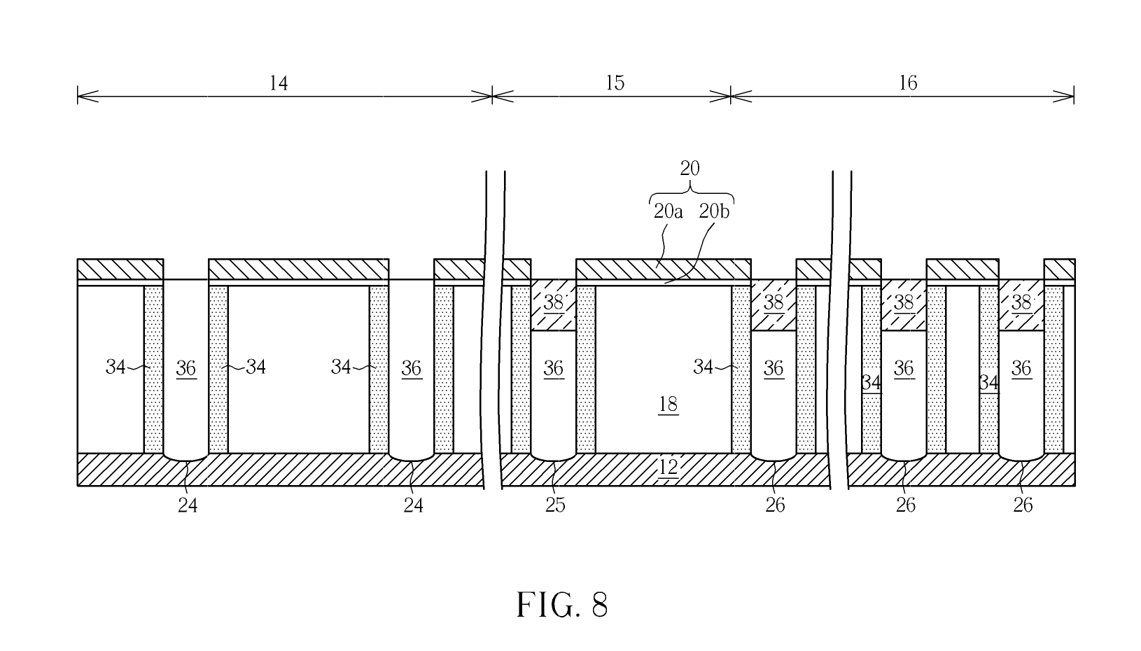

As shown in FIG. 8, a CMP process is carried out to expose the top surface of the pad layer 20. Then, a portion of the first dielectric layer 36 within the cell region 14 and a portion of the polysilicon layer 38 within the transition region 15 and the termination region 16 are etched away until the top surface of the first dielectric layer 36 and the polysilicon layer 38 are level with the top surface of the epitaxial layer 18.

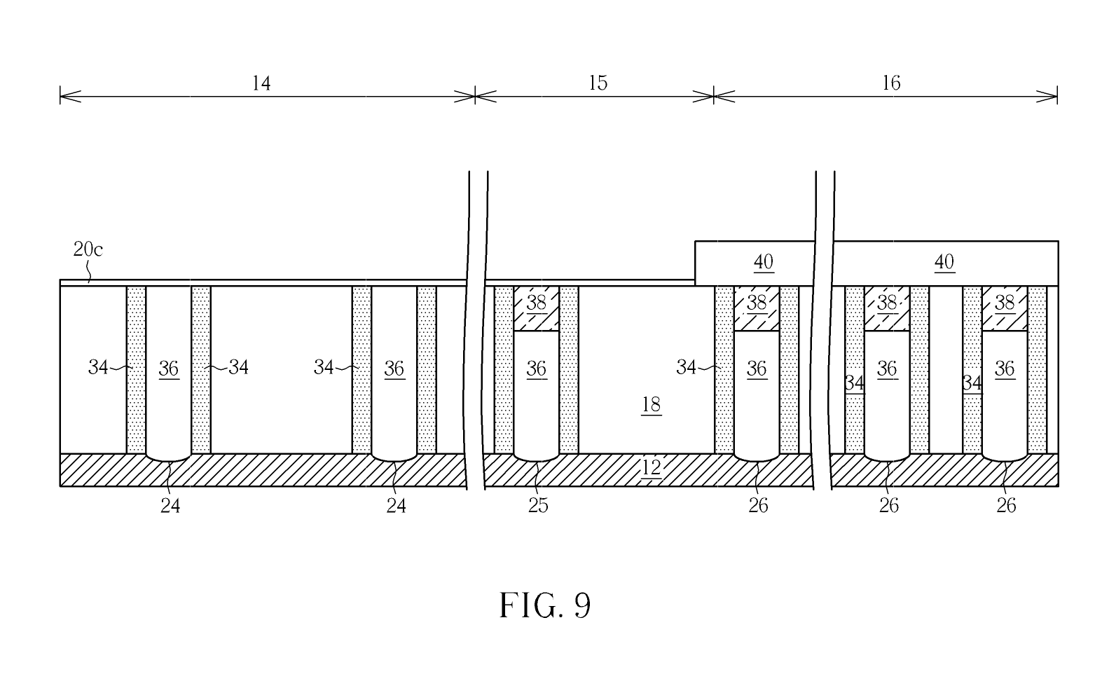

As demonstrated in FIG. 9, the upper pad layer 20a and the lower pad layer 20b are removed to expose the epitaxial layer 18. A field oxide layer 40 comprising silicon oxide is formed on the surface of the epitaxial layer 18 within the termination region 16 via conventional deposition and etching process. Then, a sacrificed oxide layer 20c is formed on the surface of the epitaxial layer 18.

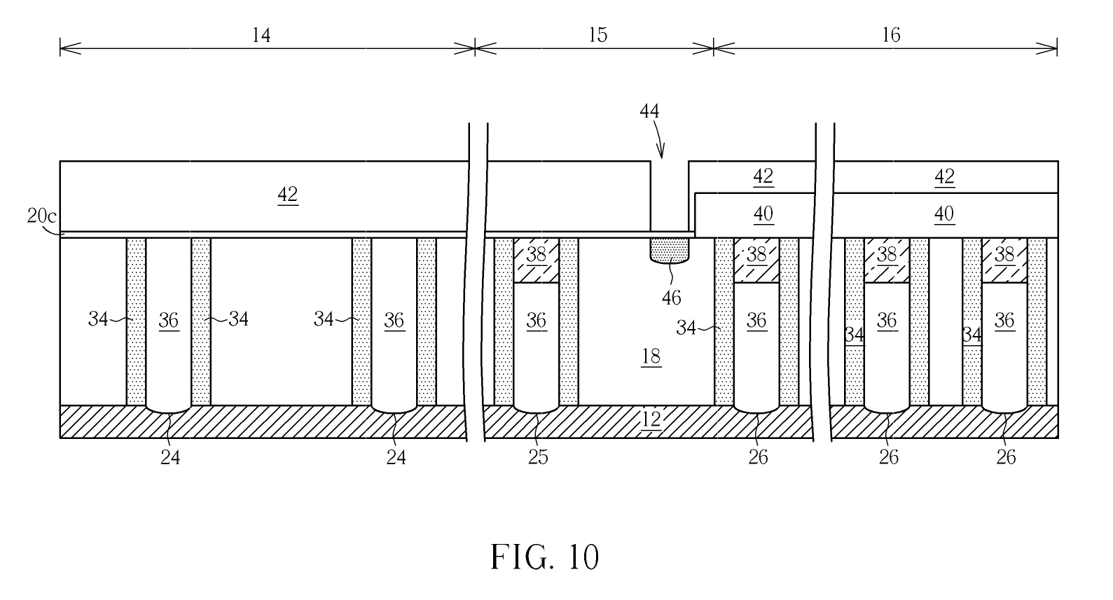

As shown in FIG. 10, a photolithography process is performed to form a photoresist pattern 42 which comprises a hole 44 exposing part of the sacrificed oxide layer 20c. The function of the hole 44 is to define the location of a guard ring. The heavily doped region 46 is formed by an ion implantation process which implants dopants into the epitaxial layer 18 through the hole 44. The photoresist pattern 42 is removed and a drive-in process is performed to activate the dopants inside the heavily doped region 46. In the preferred embodiment of the invention, the heavily doped region 46 has the second conductivity type, e.g. P-type.

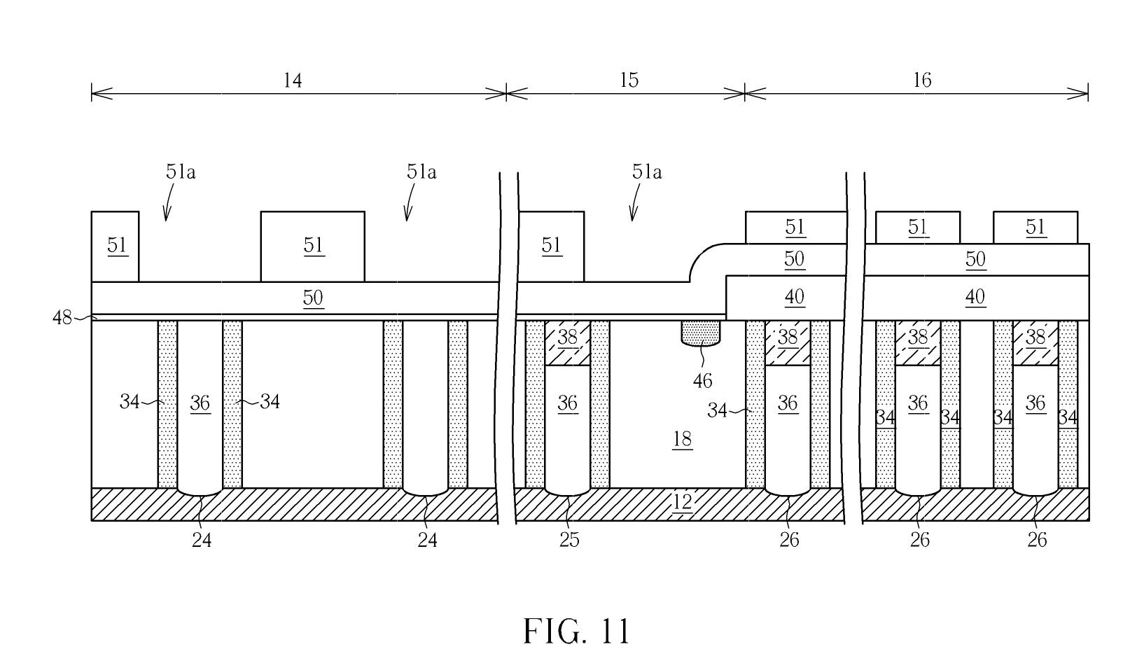

As shown in FIG. 11, the sacrificed oxide layer 20c (not shown) is removed to expose the upper surface of the epitaxial layer 18. A gate oxide layer 48 is formed on the exposed surface of the epitaxial layer 18 within the cell region 14 and the transition region 15. Then, a gate conducting layer 50 is formed. According to the preferred embodiment of the invention, the gate conducting layer 50 may comprise doped polysilicon. A photolithography process is performed to form a photoresist pattern 51, which comprises a plurality of openings 51a, to expose a portion of the gate conducting layer 50. The photoresist pattern 51 can be further transferred into the gate conducting layer 50 by an additional process.

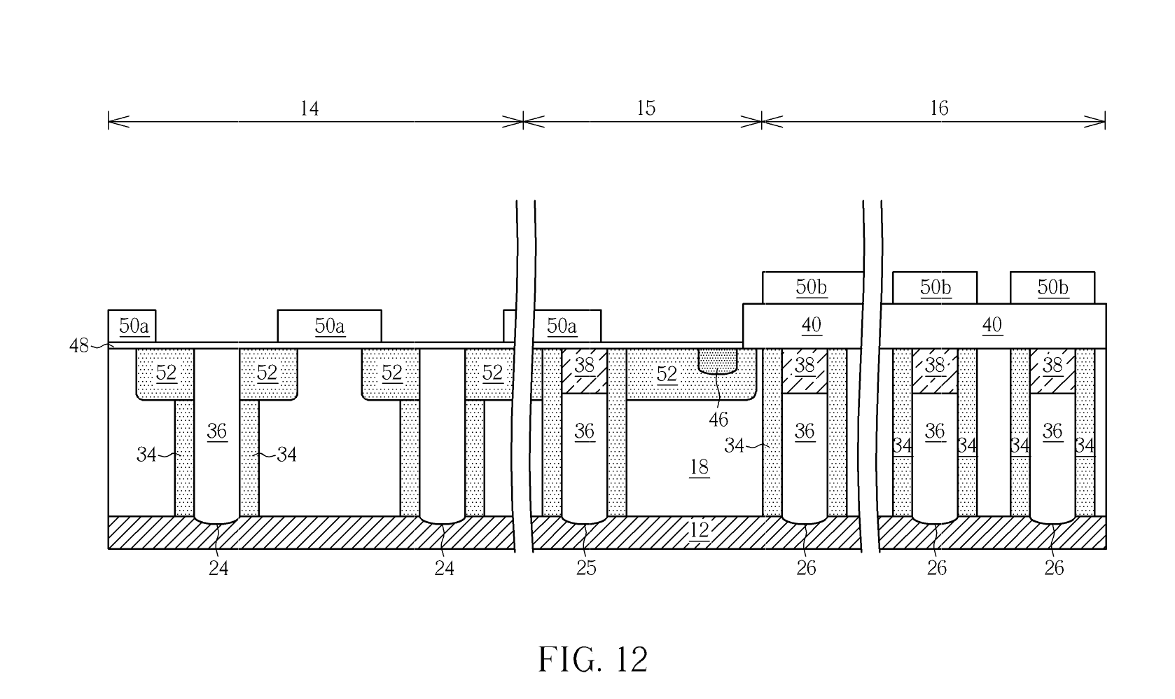

As shown in FIG. 12, by performing an etching process, a part of the gate conducting layer 50 can be etched away through the opening 51a (not shown) to form gate pattern 50a, 50b. The gate pattern 50a and the gate pattern 50b are disposed above the gate oxide layer 48 and the field oxide layer 40, respectively. Then, a self-aligned ion implantation process is performed to form an ion well 52 of the second conductivity type, e.g. P-type well, while the ion well 52 is beside the trenches 24, 25 in the epitaxial layer 18. A drive-in process may further be carried out.

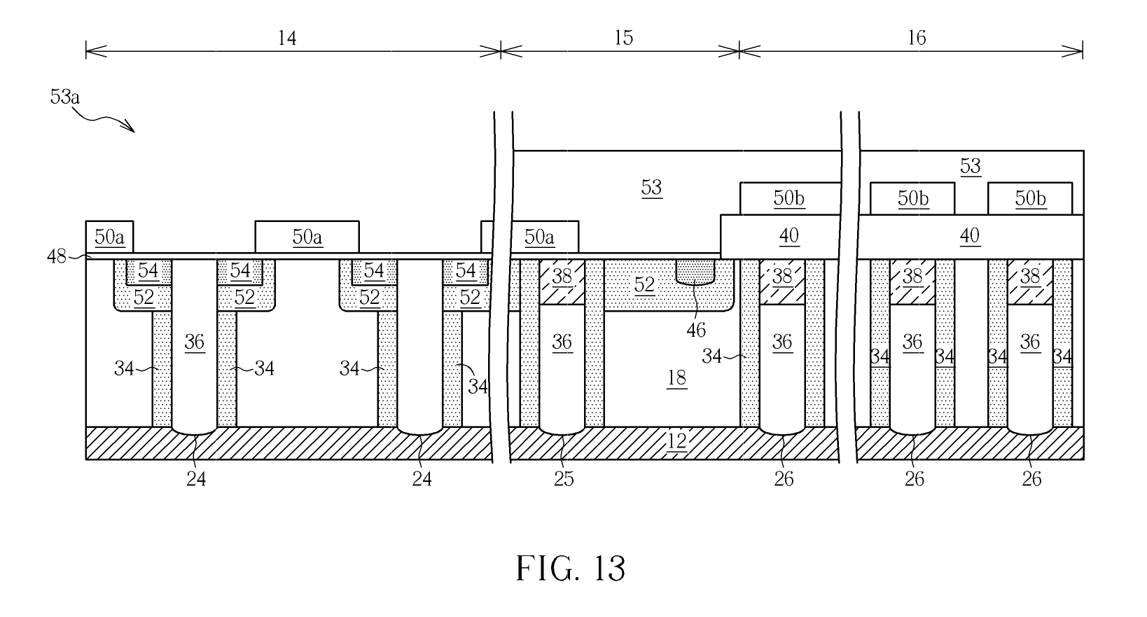

As illustrated in FIG. 13, a photoresist layer 53 is formed to expose the cell region 14 by a photolithography process. Another ion implantation process is performed to form a source doping region 54 of the first conductivity type in the ion well 52 within the cell region 14. During the ion implantation process, there is no doping region within the transition region 15 and the termination region 16 that is covered by the photoresist layer 53. Then, the photoresist layer 53 is removed and a drive-in process is performed to activate dopants in the source doping region 54.

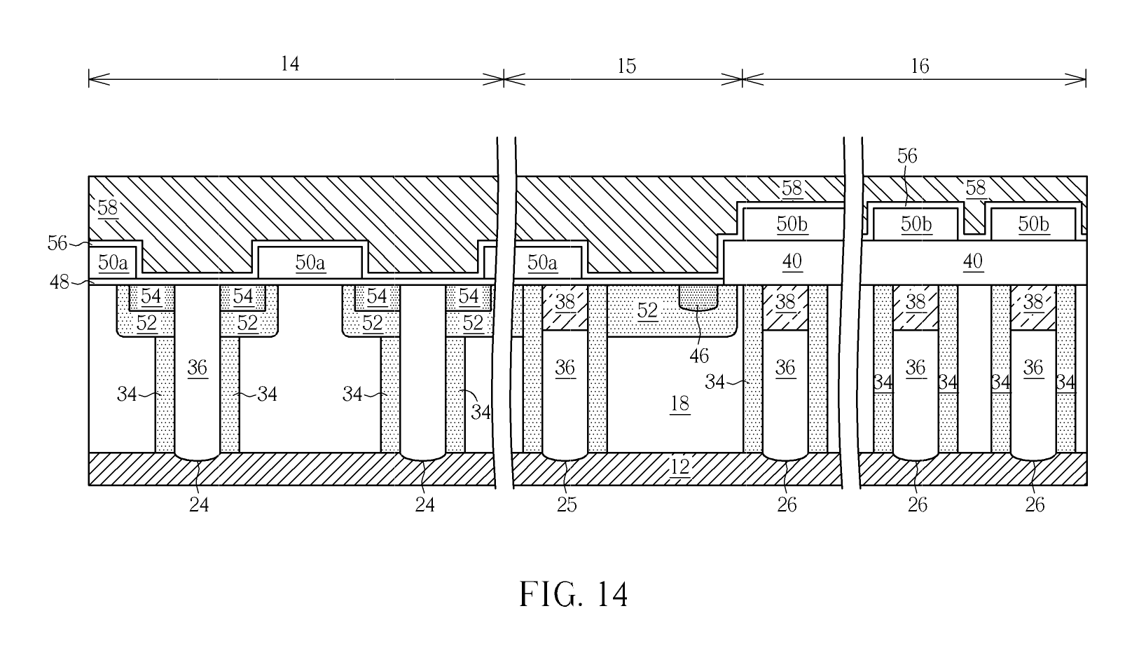

As shown in FIG. 14, a liner 56 and a second dielectric layer 58 are disposed sequentially on the surface of the cell region 14, transition region 15, and termination region 16. According to the preferred embodiment of the invention, the second dielectric layer 58 may comprise BPSG. A reflow and/or etching back process may be applied to planarize the surface of the second dielectric layer 58.

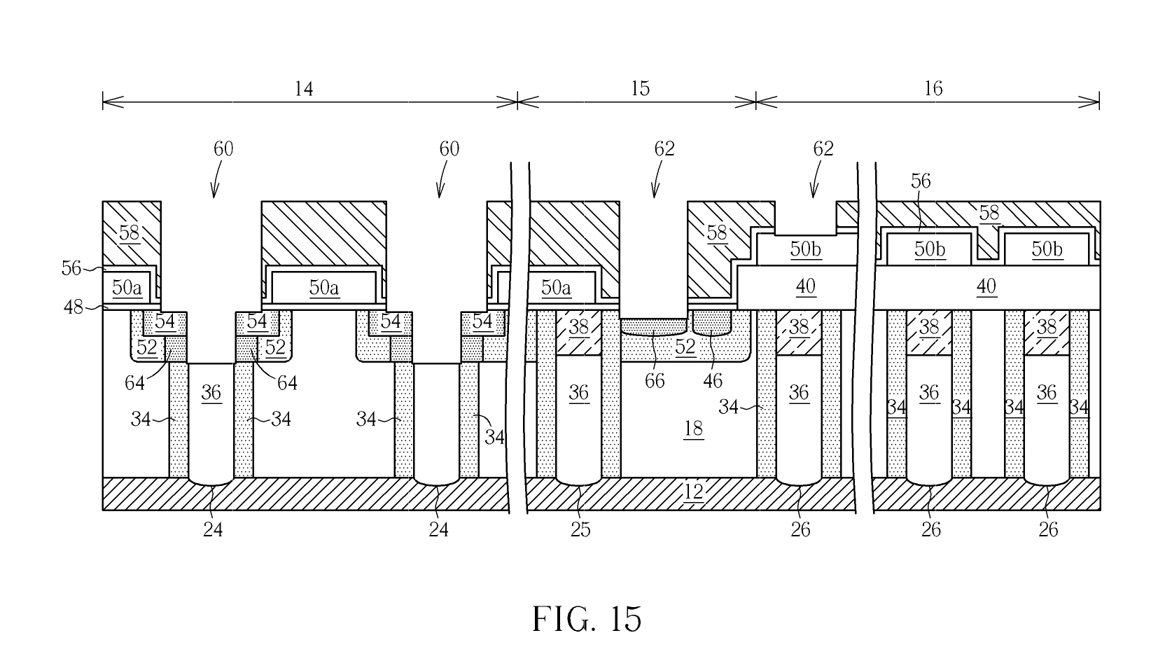

As depicted in FIG. 15, by performing a photolithography and an etching process, a portion of the second dielectric layer 58 and a portion of the liner 56, which are within the cell region 14 are etched away to form a contact opening 60 which corresponds to each trench 24 in the cell region 14. Therefore, the first dielectric layer 36 inside the trenches 24 and a portion of the source doping region 54 are exposed. At the same time, a contact opening 62 is formed above the ion well 52 and the gate pattern 50b within the transition region 15 and the termination region 16, respectively. Then, a doping region 64 of the second conductivity type is formed under the source doping region 54 by an ion implantation process. In addition, the doping region 64 is in contact with the source doping region 54. The ion implantation can form a doping region 66 of the second conductivity type in the upper portion of the exposed ion well 52 within the transition region 15. Through the above mentioned ion implantation process, the conductivity of the gate pattern 50b can be increased and the resistance between the gate pattern 50b and a metal contact can be reduced.

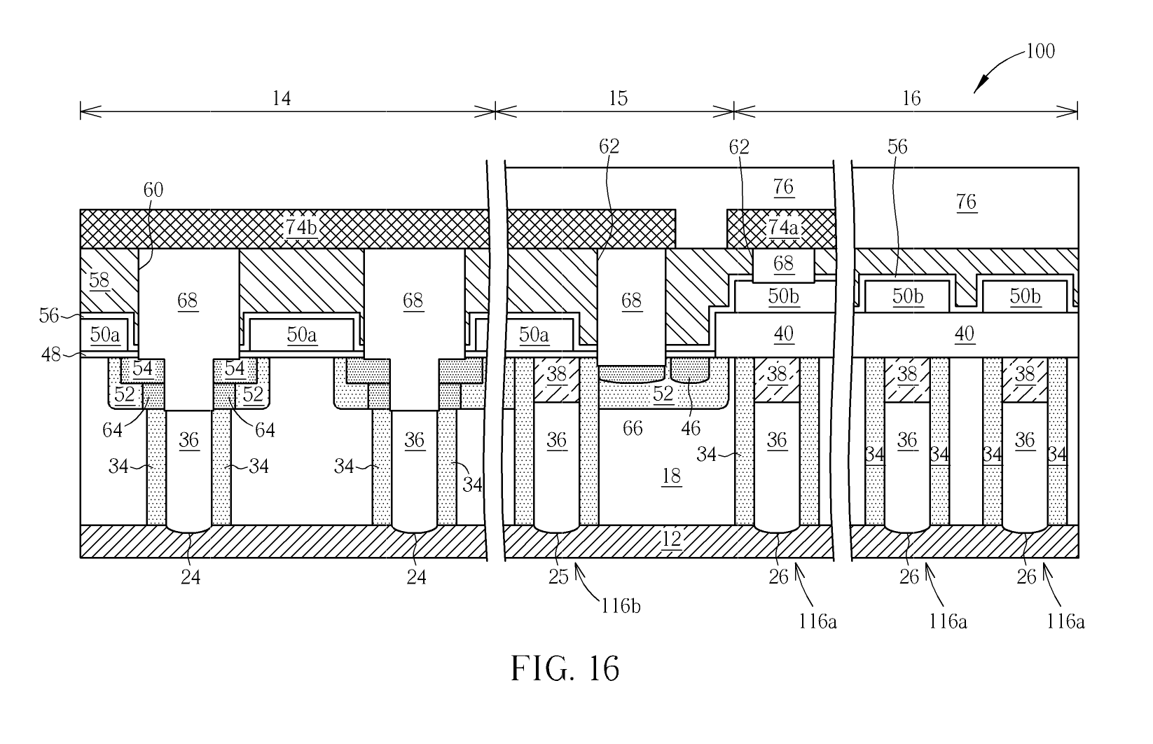

Referring to FIG. 16, a contact plug 68, which may comprise metal, e.g. tungsten or copper etc., is formed inside each contact opening 60, 62. A glue layer and/or a barrier layer may be formed before the filling of the metal layer. A conductive layer (not shown) which may comprise metal, e.g. titanium, aluminum, but is not limited thereto, is formed above the contact plug 68 and the second dielectric layer 58. Another photolithography process is performed to remove a part of the conductive layer (not shown), thereby forming at least a gate wire 74a and at least a source wire 74b. The gate wire 74a and the source wire 74b directly contact and cover the contact plug 68 within the termination region 16 and the cell region 14, respectively. A protecting layer 76, covering the gate wire 74a but exposing the source wire 74b, is formed within the transition region 15 and the termination region 16. As a result, the power device 100 described above is formed.

To summarize, the present invention provides a buffer layer located between a dopant source layer and the sidewall of trenches which can improve the distribution uniformity of dopants around the trenches after applying a drive-in process. As a result, the diffusion depths of the dopants from the sidewall are almost the same, therefore, smooth PN junctions can be obtained.

Those skilled in the art will readily observe that numerous modifications and alterations of the device and method may be made while retaining the teachings of the invention.

What is claimed is:

1. A termination structure for power devices, comprising:
a substrate of a first conductivity type;
an epitaxial layer of the first conductivity type on the substrate;
a trench in the epitaxial layer of the first conductivity type;
a first insulating layer within the trench;
a first conductive layer atop the first insulating layer within the trench; and
a column doping region of a second conductivity type disposed in the epitaxial layer of the first conductivity type adjacent to the trench, the column doping region being in direct contact with the first conductive layer.

2. The termination structure for power devices according to claim 1 wherein the first conductive layer comprises polysilicon, titanium, titanium nitride or aluminum.

3. The termination structure for power devices according to claim 1 wherein the first conductive layer is in directly contact with the first insulating layer and is substantially level with a top surface of the epitaxial layer of the first conductivity type.

4. The termination structure for power devices according to claim 1 further comprising:
a field oxide layer covering the first conductive layer and the column doping region of a second conductivity type.

5. The termination structure for power devices according to claim 4 further comprising:
a second conductive layer on the field oxide layer.

6. The termination structure for power devices according to claim 5 further comprising:
a second insulating layer covering the field oxide layer and the second conductive layer.

7. The termination structure for power devices according to claim 6 further comprising:
a gate line on the second insulating layer and a first contact plug in the second insulating layer for connecting the second conductive layer to the gate line.

8. The termination structure for power devices according to claim 1 wherein the first insulating layer is in direct contact with the substrate of the first conductivity type.

9. The termination structure for power devices according to claim 8 wherein the column doping region of a second conductivity type is connected to the substrate of the first conductivity type.

10. The termination structure for power devices according to claim 1 wherein the first conductivity type is N type and the second conductivity type is P type.

11. The termination structure for power devices according to claim 7 further comprising:
an ion well of the second conductivity type disposed in the epitaxial layer of the first conductivity type.
